(19) United States
(12) Patent Application Publication
(10) Pub. No.: US 2011/0220879 A1
(43) Pub. Date: Sep. 15, 2011

(54) Organic light emitting display

(76) Inventors: Ki Ju Im, Yongin-City (KR); Hui-Won Yang, Yongin-City (KR); Hye-Hyang Park, Yongin-City (KR); Chaun-Gi Choi, Yongin-City (KR)

(21) Appl. No.: 12/926,767

(22) Filed: Dec. 8, 2010

(30) Foreign Application Priority Data
Mar. 9, 2010 (KR) 10-2010-0021014

(51) Int. Cl. H01L 51/50

(52) U.S. Cl. 257/40; 257/E51.018

(57) ABSTRACT

An organic light emitting display (OLED) including a thin film transistor (TFT) including a gate electrode, an active layer, and source and drain electrodes, the active layer being insulated from the gate electrode and including an oxide semiconductor and the source and drain electrodes being insulated from the gate electrode and contacting the active layer; a first insulation layer covering the TFT; a second insulation layer on the first insulation layer, the second insulation layer being formed of amorphous silicon without doping; a pixel electrode on the second insulation layer; a third insulation layer on the second insulation layer, the third insulation layer covering an edge of the pixel electrode; an organic light emitting layer on the pixel electrode; and a facing electrode on the organic light emitting layer and the third insulation layer.

### BACKGROUND

1. Field

Embodiments relate to an organic light emitting display (OLED).

2. Description of the Related Art

An active matrix type organic light emitting display (OLED) may include a plurality of pixels each having a thin film transistor (TFT) and an organic light emitting device connected to the TFT.

An active layer of the TFT may generally be made of amorphous silicon or polysilicon. Recently, there have attempts to make the active layer of the TFT of an oxide semiconductor.

However, properties of the oxide semiconductor, e.g., threshold voltage and S-factor, may be easily changed due to infiltration of moisture or oxygen from the outside. In addition, since the change of the threshold voltage due to moisture or oxygen may be accelerated by a direct current (DC) bias of a gate electrode when the TFT is driven, DC stability is an important concern when an oxide semiconductor is used to make the active layer of the TFT.

To reinforce a barrier characteristic regarding moisture or oxygen for the oxide semiconductor, a film, e.g., AlOₓ or TiN, may be applied to the oxide semiconductor. However, since this film must be manufactured using, e.g., a reactive sputtering method or an atomic layer deposition (ALD) method, it may be difficult to apply the film to large-scale substrates. In addition, mass productivity of substrates to which the film is applied may also be very low.

### SUMMARY

Embodiments are directed to an organic light emitting display (OLED, which represents advances over the related art.

It is a feature of an embodiment to provide an organic light emitting display (OLED) having a thin film transistor (TFT) and a structure that prevents infiltration of moisture or oxygen from the outside.

It is another feature of an embodiment to provide an OLED that can be easily applied to large-scale display devices and has excellent mass productivity.

At least one of the above and other features and advantages may be realized by providing an organic light emitting display (OLED) including a thin film transistor (TFT) including a gate electrode, an active layer, and source and drain electrodes, the active layer being insulated from the gate electrode and including an oxide semiconductor and the source and drain electrodes being insulated from the gate electrode and contacting the active layer; a first insulation layer covering the TFT; a second insulation layer on the first insulation layer, the second insulation layer being formed of amorphous silicon without doping; a pixel electrode on the second insulation layer; a third insulation layer on the second insulation layer, the third insulation layer covering an edge of the pixel electrode; an organic light emitting layer on the pixel electrode; and a facing electrode on the organic light emitting layer and the third insulation layer.

The first insulation layer, may be formed of an organic insulation material.

The first insulation layer may be formed of a silicon oxide material or a silicon nitride material.

The third insulation layer may be formed of an organic insulation material.

The OLED may further include a fourth insulation layer between the second insulation layer and the third insulation layer.

The second insulation layer may have a thickness of about 10 to about 90 Å.

The first insulation layer and the second insulation layer may include a via hole respectively therethrough, the pixel electrode contacting the TFT through the via hole.

The pixel electrode may overlie portions of the second insulation layer adjacent to the via hole.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a partial cross-sectional view of an organic light emitting display (OLED) according to an embodiment;

FIG. 2 illustrates a magnified cross-sectional view of portion A of FIG. 1; and

FIG. 3 illustrates a partial cross-sectional view of an OLED according to another embodiment.

### DETAILED DESCRIPTION

Korean Patent Application No. 10-2010-0021014, filed on Mar. 9, 2010, in the Korean Intellectual Property Office, and entitled “Organic Light Emitting Display” is incorporated herein in its entirety by reference.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout

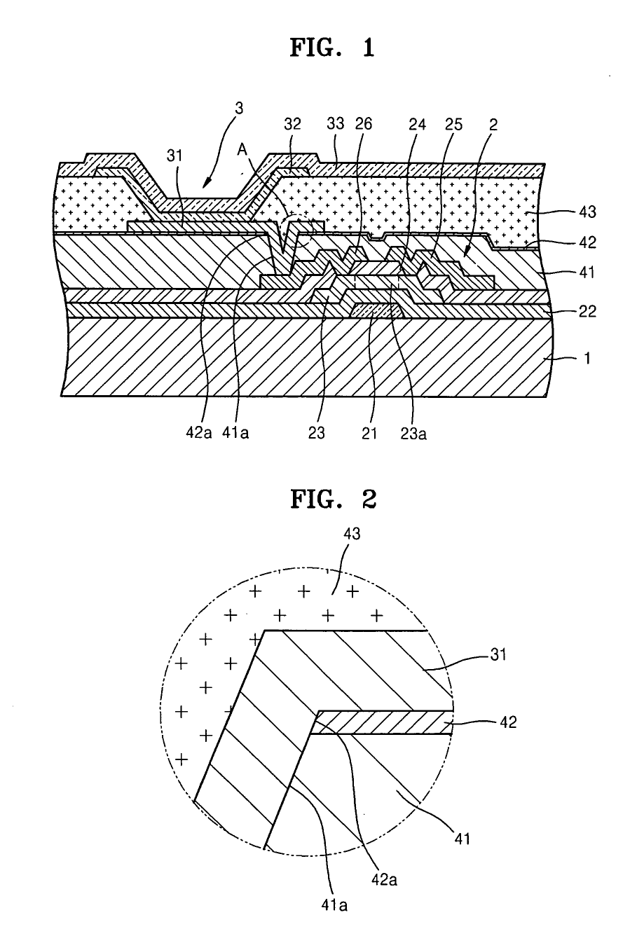

FIG. 1 illustrates a partial cross-sectional view of an organic light emitting display (OLED) according to an embodiment. FIG. 2 illustrates a magnified cross-sectional view of portion A of FIG. 1.

Referring to FIG. 1, a thin film transistor (TFT) 2 and an organic light emitting device 3 may be disposed on a substrate 1. FIG. 1 illustrates a portion of a pixel of the OLED. The OLED according to an embodiment may include a plurality of pixels.

The TFT 2 may include a gate electrode 21 on the substrate 1, a gate insulation layer 22 covering the gate electrode 21, an active layer 23 on the gate insulation layer 22, an inter-layer insulation layer 24 on the gate insulation layer 22 and covering the active layer 23, and a source electrode 25 and a drain electrode 26 on the inter-layer insulation layer 24 and contacting the active layer 23. Although FIG. 1 illustrates a bottom gate type TFT 2, the embodiments are not limited thereto. An embodiment may include a top gate type TFT in which a gate electrode is disposed on an active layer.

A buffer layer (not illustrated) formed of an inorganic material, e.g., silicon oxide, may be further formed on the substrate 1.

The gate electrode 21 on the substrate 1 may be formed in a single layer structure or plural layers structure of, e.g., a conductive metal. In an implementation, the gate electrode 21 may include, e.g., molybdenum.

The gate insulation layer 22 may be formed of, e.g., silicon oxide, tantalum oxide, or aluminum oxide, but is not necessarily limited thereto.

The active layer 23, which may be patterned, may be formed on the gate insulation layer 22. The active layer 23 may be formed of, e.g., an oxide semiconductor. For example, the active layer 23 may be a G-I-Z-O layer [(In₂O₃)ₐ(Ga₂O₃)_{b}(ZnO)_{c}] (wherein a, b, and c are real numbers satisfying conditions of a≧0, b≧0, and c>0).

The inter-layer insulation layer 24 may cover the active layer 23. The inter-layer insulation layer 24 may protect a channel 23a of the active layer 23 and may cover all of the active layer 23 except an area thereof contacting the source and drain electrodes 25 and 26, as illustrated in FIG. 1, but is not necessarily limited thereto. Although not illustrated, the inter-layer insulation layer 24 may be formed only on the channel 23a.

The source and drain electrodes 25 and 26 may be formed on the inter-layer insulation layer 24 and may contact the active layer 23.

A first insulation layer 41 may be formed on the inter-layer insulation layer 24 to cover the source and drain electrodes 25 and 26. A second insulation layer 42 may be formed on the first insulation layer 41. A first, i.e., pixel, electrode 31 of the organic light emitting device 3, which may contact the drain electrode 26, may be formed on the second insulation layer 42.

A third insulation layer 43 exposing a portion of the first electrode 31 may be formed on the second insulation layer 42. The third insulation layer 43 may overlie edges or ends of the first electrode 31. An organic layer 32 and a second, i.e., facing, electrode 33 may be formed on portions of the first electrode 31 exposed by the third insulation layer 43.

The first electrode 31 may be disposed and pattered with respect to every pixel. The second electrode 33 may be formed as a common electrode for every pixel, i.e., to cover all pixels.

In a top emission type organic light emitting display device in which an image is displayed in a direction of the second electrode 33, the first electrode 31 may act as a reflective electrode. For this purpose, a reflective film (not illustrated) formed of, e.g., an alloy of Al and Ag, may be disposed in the first electrode 31.

When the first electrode 31 is used as an anode electrode, a layer made of a metal oxide material, e.g., Indium Tin Oxide (ITO), Indium Zinc Oxide (IZO), or Zinc Oxide (ZnO), having a high work function (absolute value) may be included in the first electrode 31. When the first electrode 31 is used as a cathode electrode, a high conductive metal, such as Ag, Mg, Al, Pt, Pd, Au, Ni, Nd, Ir, Cr, Li, or Ca, having a low work function (absolute value) may be used in the first electrode 31. Accordingly, in this case, the reflective film may not be necessary.

The second electrode 33 may act as a light-transmissible electrode. For this purpose, a semi trans reflective film in which, e.g., Ag, Mg, Al, Pt, Pd, Au, Ni, Nd, Ir, Cr, Li, or Ca, is formed as a thin film may be included in the second electrode 33. Alternatively, a light-transmitting metal oxide material, e.g., ITO, IZO, or ZnO, may be included in the second electrode 33. When the first electrode 31 is used as an anode, the second electrode 33 may be used as a cathode. When the first electrode 31 is used as a cathode, the second electrode 33 may be used as an anode.

The organic layer 32 disposed between the first electrode 31 and the second electrode 33 may be formed by layering a light emitting layer and optionally a hole injection/transporting layer and/or an electron injection/transporting layer.

The hole injection/transporting layer may be formed by, e.g., vacuum thermal evaporating or spin coating a hole injection material and/or a hole transporting material.

In the case of the hole injection material, a phthalocyanine compound, e.g., copper phthalocyanine, or starburst type amines, e.g., TCTA, m-MTDATA, or m-MTDAPB, may be used.

The hole transporting material may be formed using, e.g., a vapor deposition method, a spin coating method, a cast method, or a Langmuir-Blodgett (LB) method. The hole transporting material is not specifically limited, and, e.g., N,N′-bis(3-methylphenyl)-N,N′-diphenyl-[1,1-biphenyl]-4,4′-diamine (TPD), N,N′-di(naphthalene-1-yl)-N,N′-diphenylbenzidine (α-NPD), etc., may be used.

The electron injection/transporting layer may be formed by layering at least one of an electron injection material and an electron transporting material.

For the electron injection material, e.g., LiF, NaCl, CsF, Li₂O, BaO, or Liq, may be used.

The electron transporting material is not specifically limited, and, e.g., Alq₃, may be used.

A hole blocking layer (HBL) may be selectively formed between the light emitting layer and the electron injection/transporting layer using a hole blocking material. A material for forming the HBL is not specifically limited. However, the material for forming the HBL should have a higher ionization potential compared to a light emitting compound and should also have electron transporting capability. In an implementation, e.g., Balq, BCP, or TPBI, may be used.

The light emitting layer may include a host material and a dopant material.

For the host material, e.g., tris(8-hydroxyquinolinato)aluminum (Alq₃), 9,10-di(naphth-2-yl)anthracene (ADN), 3-tert-butyl-9,10-di(naphth-2-yl)anthracene (TBADN), 4,4′-bis(2,2-diphenyl-ethene-1-yl)-4,4′-dimethylphenyl (DPVPi), 4,4′-bisBis(2,2-diphenyl-ethene-1-yl)-4,4′-dimethylphenyl (p-DMDPVBi), Tert(9,9-diarylfluorene)s (TDAF), 2-(9,9′-spirobifluorene-2-yl)-9,9′-spirobifluorene (BSDF), 2,7-bis(9,9′-spirobifluorene-2-yl)-9,9′-spirobifluorene (TSDF), bis(9,9-diarylfluorene)s (BDAF), 4,4′-bis(2,2-diphenyl-ethene-1-yl)-4,4′-di-(tert-buthyl)phenyl (p-TDPVBi), 1,3-bis(carbazole-9-yl)benzene (mCP), 1,3,5-tris(carbazole-9-yl)benzene (tCP), 4,4′,4″-tris(carbazole-9-yl)triphenylamine (TcTa), 4,4′-bis(carbazole-9-yl)biphenyl (CBP), 4,4′-bisBis(9-carbazolyl)-2,2′-dimethyl-biphenyl (CBDP), 4,4′-bis(carbazole-9-yl)-9,9-dimethyl-fluorene (DMFL-CBP), 4,4′-bis(carbazole-9-yl)-9,9-bisbis(9-phenyl-9H-carbazole)fluorene (FL-4CBP), 4,4′-bis(carbazole-9-yl)-9,9-di-tolyl-fluorene (DPFL-CBP), or 9,9-bis(9-phenyl-9H-carbazole)fluorine (FL-2CBP), may be used.

For the dopant material, e.g., DPAVBi (4,4′-bis[4-(di-p-tolylamino)styryl]biphenyl), ADN (9,10-di(naph-2-tyl)anthracene), or TBADN (3-tert-buthyl-9,10-di(naph-2-tyl)anthracene), may be used.

The hole injection/transporting layer and the electron injection/transporting layer may be common layers and may be applied to all pixels in common. Accordingly, unlike in FIG. 1, these common layers may be formed to cover all pixels like the second electrode 33.

Although not illustrated, a protection layer may be further formed on the second electrode 33 and air-tightness may be achieved using glass.

The first insulation layer 41 may be formed of an organic material, e.g., polyimides or acryl, so that the first insulation layer 41 may cover the TFT 2. A surface of the first insulation layer 41 may be planarized.

The second insulation layer 42 may be formed of, e.g., amorphous silicon without doping. Since the amorphous silicon without doping is an insulation material, it may be enough for the second insulation layer 42 to electrically separate the first electrode 31 for every pixel.

The second insulation layer 42 may be formed to have a thickness of about 10 to about 90 Å.

The second insulation layer 42 formed of, e.g., amorphous silicon without doping, may have a hydrophobic property with respect to the surface of the first insulation layer 41, thereby protecting the TFT 2 from moisture infiltrating from outside of the device.

Maintaining the thickness of the second insulation layer 42 at about 10 Å or greater may help ensure that the second insulation layer 42 is able to act as a protection film against moisture. Maintaining the thickness of the second insulation layer 42 at about 90 Å or less may help ensure that the second insulation layer 42 has a hydrophobic property with respect to the surface of the first insulation layer 41.

A first via hole 41a and a second via hole 42a may be respectively formed in the first insulation layer 41 and the second insulation layer 42. The first via hole 41a and the second via hole 42a may be connected to each other, thereby facilitating contact between the first electrode 31 and the TFT 2, e.g., the drain electrode 26.

Accordingly, as illustrated in FIG. 2, a surface of the second insulation layer 42 may contact the first electrode 31. In addition, the second insulation layer 42 may not be disposed in a contact region of the first electrode 31 and the drain electrode 26. Thus, degradation of a contact characteristic of the first electrode 31 and the drain electrode 26 due to the second insulation layer 42 may be advantageously prevented. In addition, the first electrode 31 may overlie edges of the second insulation layer 42 adjacent to the via hole, thereby improving the prevention of infiltration of moisture.

The third insulation layer 43 formed on the second insulation layer 42 may be formed of, e.g., an organic insulation material. By forming the third insulation layer 43 on the second insulation layer 42 having a hydrophobic property, infiltration of moisture through an interface between the second insulation layer 42 and the third insulation layer 43 may be prevented.

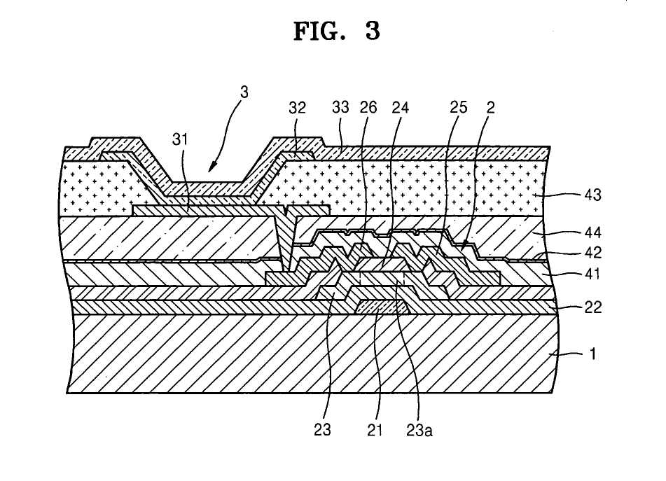

FIG. 3 illustrates a partial cross-sectional view of an OLED according to another embodiment. In the present embodiment, the first insulation layer 41 may be formed of e.g., a silicon oxide material or a silicon nitride material.

By forming the first insulation layer 41 of an inorganic material, the effect of preventing infiltration of moisture may be increased.

After forming the second insulation layer 42 on the first insulation layer 41, a fourth insulation layer 44 may be formed of the organic material described above with respect to the third insulation layer 43, to cover the second insulation layer 42. The first electrode 31 may be formed on the fourth insulation layer 44. A surface of the fourth insulation layer 44 may be planarized.

According to the embodiments, since the second insulation layer may have a hydrophobic property with respect to the surface of the first insulation layer, infiltration of moisture may be more effectively prevented, thereby fully protecting the active layer from moisture or oxygen.

In addition, an effect of preventing infiltration of moisture through an interface between the second insulation layer and the third insulation layer or between the second insulation layer and the fourth insulation layer may be obtained.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An organic light emitting display (OLED), comprising:
a thin film transistor (TFT) including a gate electrode, an active layer, and source and drain electrodes, the active layer being insulated from the gate electrode and including an oxide semiconductor and the source and drain electrodes being insulated from the gate electrode and contacting the active layer;
a first insulation layer covering the TFT;
a second insulation layer on the first insulation layer, the second insulation layer being formed of amorphous silicon without doping;
a pixel electrode on the second insulation layer;
a third insulation layer on the second insulation layer, the third insulation layer covering an edge of the pixel electrode;
an organic light emitting layer on the pixel electrode; and
a facing electrode on the organic light emitting layer and the third insulation layer.

2. The OLED as claimed in claim 1, wherein the first insulation layer is formed of an organic insulation material.

3. The OLED as claimed in claim 1, wherein the first insulation layer is formed of a silicon oxide material or a silicon nitride material.

4. The OLED as claimed in claim 1, wherein the third insulation layer is formed of an organic insulation material.

5. The OLED as claimed in 1, further comprising a fourth insulation layer between the second insulation layer and the third insulation layer.

6. The OLED as claimed in 1, wherein the second insulation layer has a thickness of about 10 to about 90 Å.

7. The OLED as claimed in 1, wherein the first insulation layer and the second insulation layer include a via hole respectively therethrough, the pixel electrode contacting the TFT through the via hole.

8. The OLED as claimed in claim 7, wherein the pixel electrode overlies portions of the second insulation layer adjacent to the via hole.
